(19) United States
(12) Patent Application Publication
(10) Pub. No.: US 2007/0114549 A1
(43) Pub. Date: May 24, 2007

(54) LIGHT-EMITTING DIODE

(75) Inventor: SHENG-JUNG YU, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,315

(22) Filed: Jul. 25, 2006

(30) Foreign Application Priority Data
Nov. 23, 2005 (CN) 200510101770.6

(51) Int. Cl. H01L 33/00

(52) U.S. Cl. 257/98

(57) ABSTRACT

A light-emitting diode (20) includes a base (22), an LED chip (24) and a single-piece enclosure (26). The LED chip is electrically mounted on the base configured for emitting light beams. The single-piece enclosure attaches to the base and encloses the LED chip therein. The enclosure includes a central convergent lens portion (260) configured for converging the light beams from the LED chip. A peripheral portion (262) surrounds and extends from the central convergent lens portion to the base. The central convergent lens portion has an outer aspheric surface (264) and is aligned with the LED chip.

### 1. FIELD OF THE INVENTION

The present invention relates generally to light-emitting devices and more particularly to a light-emitting diode (LED)

### 2. DESCRIPTION OF RELATED ART

At present, fluorescence lamps are popularly used as illumination tools. However the mercury used in the fluorescence lamps represents a great danger to environment when the fluorescence lamps are damaged and/or reclaimed, and many researchers have suggested using LEDs to replace them. This would also have the advantage of greater convenience as the lifespan of the LEDs is longer than that of the fluorescent lamps and the LEDs would therefore not need to be replaced so often. Therefore using LED light sources to replace fluorescent lamps has become seen as the way of the future.

The LEDs are semiconductor devices that can convert electrical energy directly into light, due to the nature of the recombination of electrons and holes that occurs in the semiconductor solid. The LEDs rely on this recombination process to emit light.

Generally, a LED has a hemispherical lens of a type well known in the art. However, the hemispherical surface of the lens can lead to optical aberration. When observed along a package axis the light emitted from the LED chip is dispersed. As a result, the intensity and the utility of such an LED cannot satisfy the needs of illumination.

Therefore, what is needed, is a light-emitting diode with a high light utilization ratio.

### SUMMARY OF THE INVENTION

A light-emitting diode includes a base, an LED chip and a single-piece enclosure. The LED chip is electrically mounted on the base, and configured for emitting light beams. The single-piece enclosure attaches to the base and encloses the LED chip therein. The enclosure includes a central convergent lens portion configured for converging the light beams from the light-emitting diode chip. A peripheral portion surrounds and extends from the central convergent lens portion to the base. The central convergent lens has an outer aspheric surface and is aligned with the LED chip.

### BRIEF DESCRIPTION OF THE DRAWINGS

Many aspects of the present light-emitting diode can be better understood with reference to the following drawing. The components in the drawing are not necessarily drawn to scale, the emphasis instead being placed upon clearly illustrating the principles of the present light-emitting diode. Moreover, in the drawing like reference numerals designate corresponding parts throughout.

FIG. 1 is a schematic, cross-sectional view of a light-emitting diode in accordance with a preferred embodiment.

### DETAILED DESCRIPTION OF THE INVENTION

Reference will now be made to the drawings to describe in detail the preferred embodiments of the present light-emitting diode.

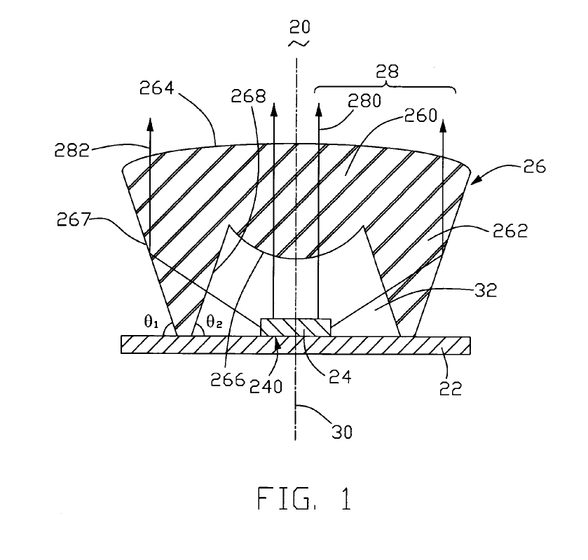

FIG. 1 illustrates an exemplary light-emitting diode 20 in accordance with one embodiment. The light-emitting diode 20 includes a base 22, an LED chip 24, and a single-piece enclosure 26. The LED chip 24 is electrically mounted on the base 22, and configured for emitting light beams. The single-piece enclosure 26 is light-permeable, and preferably transparent. The single-piece enclosure 26 attaches to the base 22 and encloses the LED chip 24 therein. The enclosure 26 includes a central convergent lens portion 260 configured for converging the light beams from the LED chip 24. A peripheral portion 262 surrounds and extends from the central convergent lens portion 260 to the base 22. The central convergent lens portion 260 has an outer aspheric surface 264 and is aligned with the LED chip 24. The light-emitting diode 20 defines a longitudinal axis 30 passing through the center of the base 22, the LED chip 24 and the enclosure 26 in turn.

The central convergent lens portion 260 faces the LED chip 24 and the peripheral portion 262 is coupled to the base 22. The central convergent lens portion 260 includes an outer aspheric surface 264 and an incident surface 266. The incident surface 266 faces the LED chip 24 and the outer aspheric surface 264 faces outside of the light-emitting diode 20. The aspheric surface mainly includes a quadric surface and a highly curved surface. Radius of curvature of the aspheric surface is changeable with positions of points on the aspheric surface. The aspheric surface can be a hyperbolic surface, an ellipse surface, a parabolic surface, and etc. In the illustrated embodiment, the aspheric surface is an ellipse-shaped surface. Lenses with aspheric surface can reduce optical aberration, so that imaging and spotlighting using the aspheric lens is better than that of a spherical lens. It is to be noted that although only outer aspheric surface 264 is exemplarily illustrated herein, the incident surface can also be an aspheric surface, which can be alternatively selected according to practical application within the spirit of the present invention.

The peripheral portion 262 is coupled with the base 22 and is configured for refracting and bending light 28 so that the light 28 exits from the central convergent lens portion 260 as parallel to the longitudinal package axis 30 as possible. The peripheral portion 262 of the enclosure 26 tapers in a direction from the central convergent lens portion 260 to the base 22. The interface between the enclosure 26 and the base 22 may be sealed using any sealant, such as a room temperature vulcanizing (RTV) sealant or the like. A first angle θ1 between an outer surface 267 of the peripheral portion 262 and the base 22 is configured to be in the range from about 0 to about 90 degrees. A second angleθ2 between an inner surface 268 of the peripheral portion 262 and the base 22 is in the range from about 0 to about 90 degrees. Preferably, the first angleθ1 and the second angleθ2 are in the range from 45 to 80 degree. The outer surface 267 of the peripheral portion 262 may be in contact with, or coated with, a reflective material so that the peripheral portion 262 can reflect light emitted from the LED chip 22 into the central convergent lens portion 260.

The enclosure 26 may be manufactured as a separate component using a number of well-known techniques such as diamond turning (i.e. shaping the enclosure using a lathe with a diamond-bit), injection molding, and casting. The enclosure 26 can be made of a transparent material including but not limited to cyclic olefin copolymer (COC), polymethylmethacrolate (PMMA), polycarbonate (PC), PC and/or PMMA, and polyetherimide (PIE). The enclosure 26 includes an index of refraction (n) ranging from between 1.45 to 1.6, and preferably with a value of about 1.55, but with higher or lower values of index of refraction being possible based on the material used. In an alternative embodiment, the enclosure 26 may be formed onto the base 22 and the LED chip 24 by various techniques including but not limited to injection molding and casting.

As illustrated in FIG. 1, the base 22 supports the LED chip 24 for generating light. The base 22 is a flexible printed circuit board (FPCB). The LED chip 24 connects with the FPCB electrically. In the illustrated embodiment, the LED chip 24 is preferably a surface mount device (SMD) light-emitting diode chip with a power greater than one watt. The LED chip 24 may be one of any number of shapes, including but not limited to a cube, a rectangular solid, a truncated inverted pyramid (TIP) or a hemisphere. In the illustrated embodiment, the shape of the LED chip 24 is a rectangular solid. The LED chip 24 includes a bottom surface 240 that may be in contact with, or coated with, a reflective material. Although the LED chip 24 may emit light from all of its sides, the base 22 is generally configured to reflect emitted light upwards towards the enclosure 26 along the longitudinal axis 30 of the light-emitting diode 20.

There is a volume 32 between the enclosure 26 and the base 22. The volume 32 may be filled and sealed to prevent contamination of the enclosure 26 using silicone. The volume 32 may also be in a vacuum state, contain air or some other gas, or filled with an optically transparent resin material, including but not limited to resin, silicone, epoxy, water or any material with an index of refraction in the range of 1.4 to 1.6 may be injected to fill the volume 32. The material inside the volume 32 may be colored to act as a filter in order to allow transmission of all or only a portion of the visible light spectrum. If silicone is used, the silicone may be hard or soft. The enclosure 26 may also be colored to act as a filter.

In operation, a part of light 280 emitted from the LED chip 24 passes through the central convergent lens portion 260, and the central convergent lens portion 260 converges the light 280. Another part of light 282 is incident onto the peripheral portion 262, and is then reflected by the outer surface 267 of the peripheral portion 262 and spreads out from the outer aspheric surface 264 of the central convergent lens portion 260.

While the present invention has been described as having preferred or exemplary embodiments, the embodiments can be further modified within the spirit and scope of this disclosure. This application is therefore intended to cover any variations, uses, or adaptations of the embodiments using the general principles of the invention as claimed. Further, this application is intended to cover such departures from the present disclosure as come within known or customary practice in the art to which the invention pertains and which fall within the limits of the appended claims or equivalents thereof.

What is claimed is:

1. A light-emitting diode comprising:
a base;
a light-emitting diode chip electrically mounted on the base, the light-emitting diode chip configured for emitting light beams; and
a single-piece enclosure attached to the base enclosing the light-emitting diode chip therein, the enclosure comprising a central convergent lens portion configured for converging the light beams from the light-emitting diode chip, and a peripheral portion surrounding and extending from the central convergent lens portion to the base, the central convergent lens having an outer aspheric surface and aligned with respect to the light-emitting diode chip.

2. The light-emitting diode as described in claim 1, wherein the peripheral portion of the enclosure tapers in a direction from the central convergent portion to the base.

3. The light-emitting diode as described in claim 1, wherein the central convergent lens portion has an inner aspheric surface or an inner spherical surface.

4. The light-emitting diode as described in claim 1, wherein the enclosure is sealed with the base using a sealant.

5. The light-emitting diode as described in claim 1, wherein the peripheral portion of the enclosure comprises an outer surface, the outer surface and the base defining a first angle, the first angle being in the range from above about 0 to about 90 degrees.

6. The light-emitting diode as described in claim 5, wherein the first angle is in the range from 45 to 80 degrees.

7. The light-emitting diode as described in claim 1, wherein the peripheral portion comprises an inner surface, the inner surface and the base defining a second angle, the second angle being in the range from above about 0 to about 90 degrees.

8. The light-emitting diode as described in claim 7, wherein the second angle is in the range from 45 to 80 degrees.

9. The light-emitting diode as described in claim 1, wherein the base is a flexible printed circuit board.

10. The light-emitting diode as described in claim 1, wherein the light-emitting diode chip is a surface mount device light-emitting diode chip.

11. The light-emitting diode as described in claim 1, wherein the aspheric surface is a quadric surface.

12. The light-emitting diode as described in claim 1, wherein the aspheric surface is a highly curved surface.

13. The light-emitting diode as described in claim 1, wherein the aspheric surface is selected from one of a hyperbolic surface, an ellipse surface, and a parabolic surface.

14. The light-emitting diode as described in claim 1, wherein the enclosure has an index of refraction in the range from 1.45 to 1.6.

15. A light-emitting diode comprising:
a base;
a light-emitting diode chip electrically mounted on the base, the light-emitting diode chip configured for emitting light beams; and
an light-permeable enclosure attached to the base enclosing the light-emitting diode chip therein, the enclosure comprising a central convergent lens portion configured for converging the light beams from the light-emitting diode chip, and a peripheral portion surrounding and extending from the central convergent lens portion to the base, the central convergent lens having an outer aspheric surface, the peripheral portion having an outer surface configured for reflecting and directing the light beams from the light-emitting diode chip to exit from the outer aspheric surface of the central convergent lens.
